(19) United States
(12) Patent Application Publication
(10) Pub. No.: US 2025/0149431 A1
(43) Pub. Date: May 8, 2025

(54) MANUFACTURING METHOD OF ELECTRONIC PACKAGE AND ELECTRONIC PACKAGE

(71) Applicant: VIA Technologies, Inc., New Taipei City (TW)

(72) Inventors: Wen-Yuan Chang, New Taipei City (TW); Wei-Cheng Chen, New Taipei City (TW); Chen-Yueh Kung, New Taipei City (TW)

(73) Assignee: VIA Technologies, Inc., New Taipei City (TW)

(21) Appl. No.: 18/765,344

(22) Filed: Jul. 8, 2024

Related U.S. Application Data
(60) Provisional application No. 63/595,343, filed on Nov. 2, 2023.

(30) Foreign Application Priority Data
May 8, 2024 (TW) 113117028

(51) Int. Cl. H01L 23/498; H01L 21/48; H01L 21/68; H01L 23/00; H01L 23/538; H01L 25/065

(52) U.S. Cl. CPC H01L 23/49838; H01L 21/4857; H01L 21/486; H01L 21/68; H01L 23/49822; H01L 23/5386; H01L 24/08; H01L 24/80; H01L 25/0655; H01L 2224/08235; H01L 2224/80895; H01L 2224/80896; H01L 2924/1815

(57) ABSTRACT

A manufacturing method of an electronic package includes the following steps. A first interfacial dielectric layer is formed to cover sides of multiple first conductive vias and multiple second conductive vias. Multiple chips are directly bonded to the first and second conductive vias. A base dielectric layer is formed to fill a gap between the adjacent chips. A bridge element is directly bonded to the first conductive vias, such that the bridge element partially overlaps the adjacent chips respectively. A second interfacial dielectric layer and multiple third conductive vias are formed on the first interfacial dielectric layer and the bridge element. A redistribution circuit structure is formed on the second interfacial dielectric layer and the third conductive vias. Multiple conductive bumps are formed on the redistribution circuit structure. An electronic package is also provided.

### CROSS-REFERENCE TO RELATED APPLICATION

This application claims the priority benefit of U.S. provisional application Ser. No. 63/595,343, filed on Nov. 2, 2023 and Taiwan patent application no. 113117028, filed on May 8, 2024. The entirety of each of the above-mentioned patent applications is hereby incorporated by reference herein and made a part of this specification.

### BACKGROUND

### Technical Field

The disclosure relates to an electronic part, and in particular to a manufacturing method of an electronic package and an electronic package.

### Description of Related Art

Currently, there are many types of electronic packaging technologies for multi-chip applications. One such type involves forming an interconnection circuit structure on a bridge element, and then bonding multiple chips to the interconnection circuit structure using micro bumps containing solder through a flip-chip method. A bridge element overlapping multiple adjacent chips can shorten signal transmission paths between the adjacent chips. To protect the chips and the bridge element, a known approach is adopting a molding compound to encapsulate the bridge element and the chips. However, even if the chips are accurately positioned, injecting the molding compound may still result in an offset of the chips. Moreover, the thermal curing of the molding compound may cause an accumulation of stress between the chips and the material due to the significant difference in the coefficients of thermal expansion.

### SUMMARY

The disclosure provides a manufacturing method of an electronic package for manufacturing the electronic package.

The disclosure provides an electronic package for providing good packaging quality.

In an embodiment of the disclosure, a manufacturing method of an electronic package includes the following steps. A first interfacial dielectric layer, multiple first conductive vias, and multiple second conductive vias are formed on a first temporary carrier. The first interfacial dielectric layer covers the first temporary carrier, the sides of the first conductive vias, and the sides of the second conductive vias. The chips are mounted on the first interfacial dielectric layer. Multiple first chip pads and multiple second chip pads on an active surface of each of the chips are directly bonded to the first conductive vias and the second conductive vias respectively. A base dielectric layer is formed to cover the first interfacial dielectric layer and the sides of the chips. The base dielectric layer fills a gap between the adjacent chips. The first temporary carrier is removed. The chips and the first interfacial dielectric layer are fixed to a second temporary carrier. A bridge element is mounted on the first interfacial dielectric layer, enabling the bridge element to partially overlap the adjacent chips respectively. Multiple bridge pads of the bridge element are directly bonded to the first conductive vias respectively. A second interfacial dielectric layer and multiple third conductive vias are formed on the first interfacial dielectric layer and the bridge element. The third conductive vias pass through the second interfacial dielectric layer to be connected to the second conductive vias respectively. A redistribution circuit structure is formed on the second interfacial dielectric layer and the third conductive vias. Multiple conductive bumps are formed on the redistribution circuit structure. The second temporary carrier is removed.

In an embodiment of the disclosure, an electronic package includes a sub-package. The sub-package includes multiple chips, multiple first conductive vias, multiple second conductive vias, a first interfacial dielectric layer, at least one bridge element, a second interfacial dielectric layer, multiple third conductive vias, a redistribution circuit structure, and multiple conductive bumps. The chips are arranged in a plane. An active surface of each of the chips has multiple first chip pads and multiple second chip pads. The first conductive vias are directly bonded to the first chip pads respectively. The second conductive vias are directly bonded to the second chip pads respectively. The first interfacial dielectric layer covers the sides of the first conductive vias and the sides of the second conductive vias. The first interfacial dielectric layer fills a gap between the adjacent chips. The bridge element partially overlaps the adjacent chips respectively. Multiple bridge pads of the bridge element are directly bonded to the first conductive vias respectively. The second interfacial dielectric layer is located on the first interfacial dielectric layer and the bridge element. The third conductive vias pass through the second interfacial dielectric layer to be connected to the second conductive vias respectively. An outer diameter of the third conductive via is smaller than an outer diameter of the second chip pad connected to the second conductive via. The redistribution circuit structure is disposed on the second interfacial dielectric layer and the third conductive vias. The conductive bumps are disposed on the redistribution circuit structure.

Based on the above, in the embodiment, the bridge element is bonded to the chips through the first conductive vias located in the first interfacial dielectric layer in case of direct bonding. In addition, the chips are electrically connected to a redistribution circuit layer through the second conductive via located in the first interfacial dielectric layer and the third conductive via located in the second interfacial dielectric layer. With the direct bonding, the problem of chip misalignment caused by the use of molding compound between the chips and bridge elements can be solved.

### BRIEF DESCRIPTION OF THE DRAWINGS

FIGS. 1A to 1S illustrate a manufacturing method of an electronic package in an embodiment of the disclosure.

FIGS. 2A to 2C are alternative steps for the steps in FIGS. 1C to 1F.

FIG. 3A illustrates an electronic package in another embodiment of the disclosure.

FIG. 3B illustrates a partially enlarged view of the electronic package in FIG. 3A.

FIGS. 4A to 4S illustrate a manufacturing method of an electronic package in another embodiment of the disclosure.

FIGS. 5A to 5C are alternative steps for the the steps in FIGS. 4C to 4F.

FIG. 6A illustrates an electronic package in another embodiment of the disclosure.

FIG. 6B illustrates a partially enlarged view of the electronic package in FIG. 6A.

### DESCRIPTION OF THE EMBODIMENTS

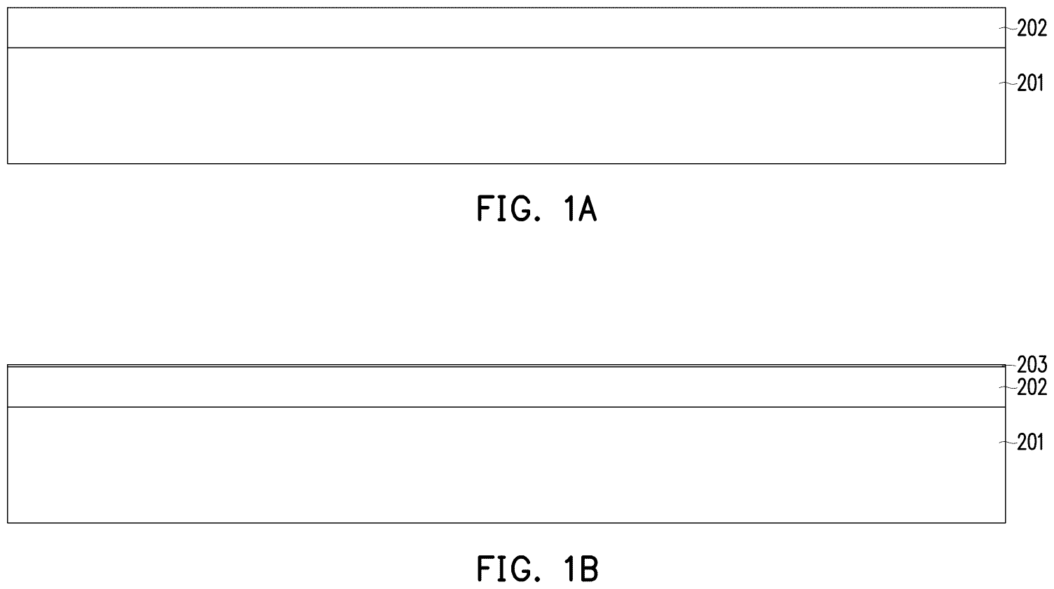

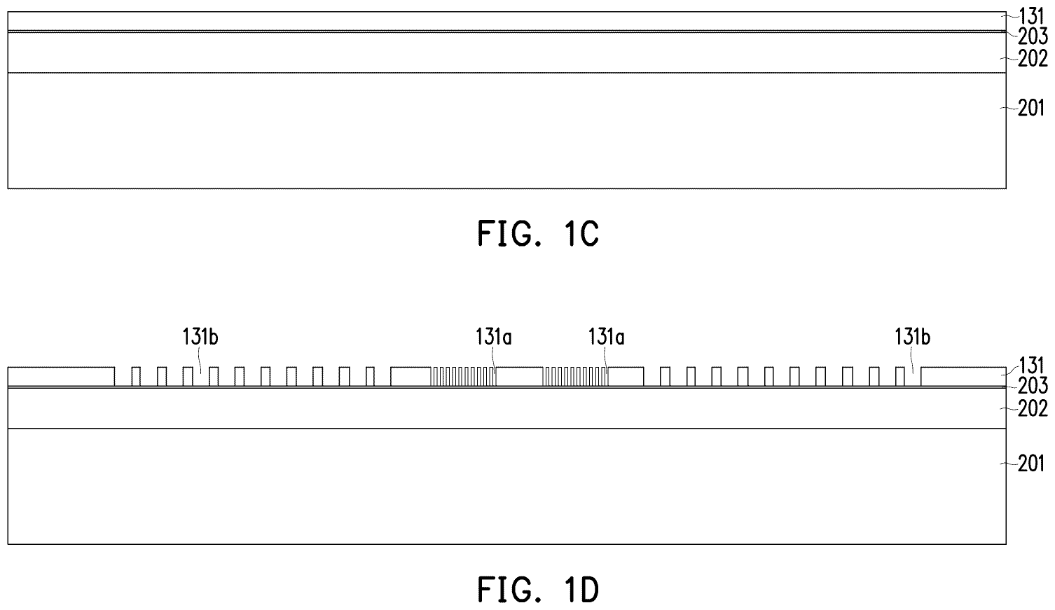

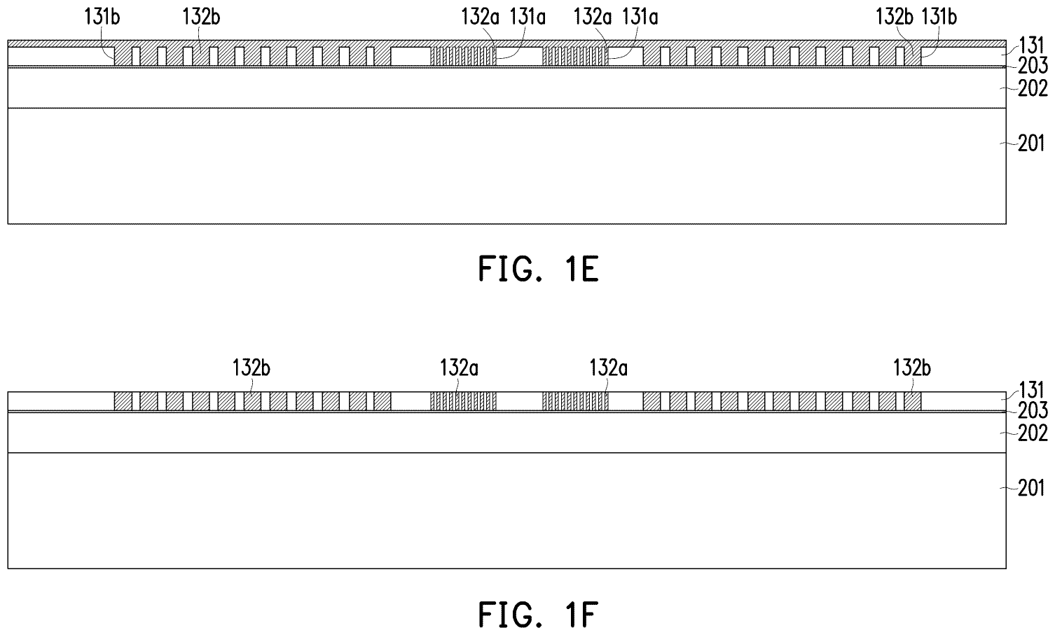

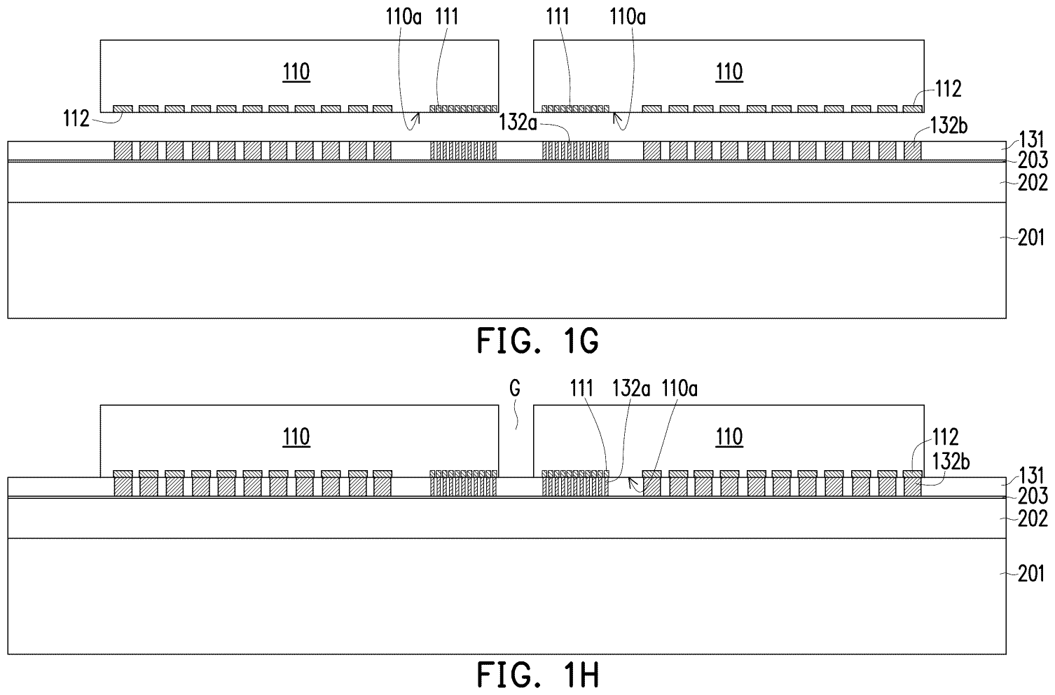

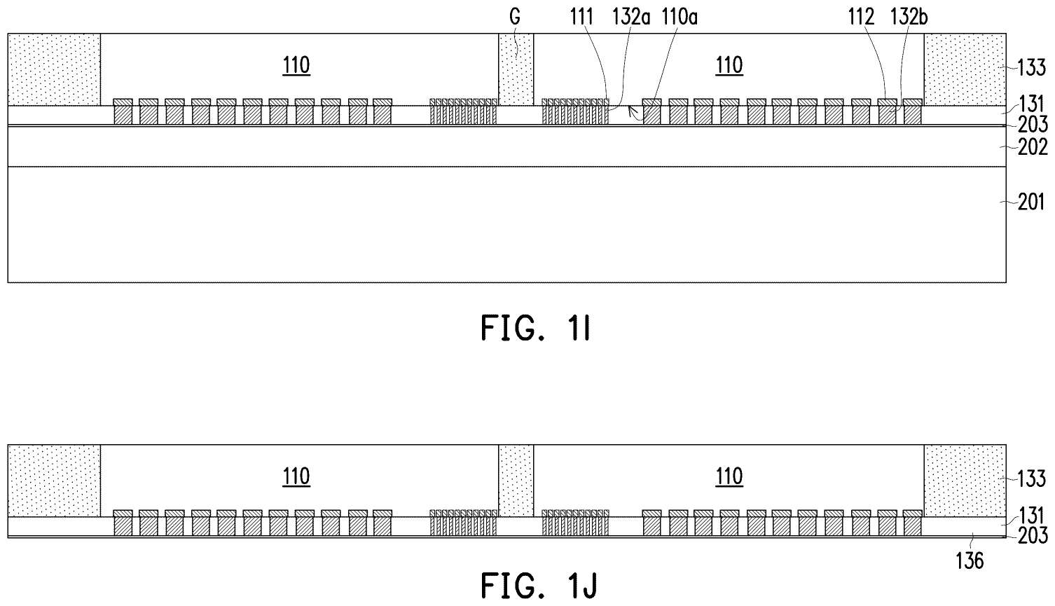

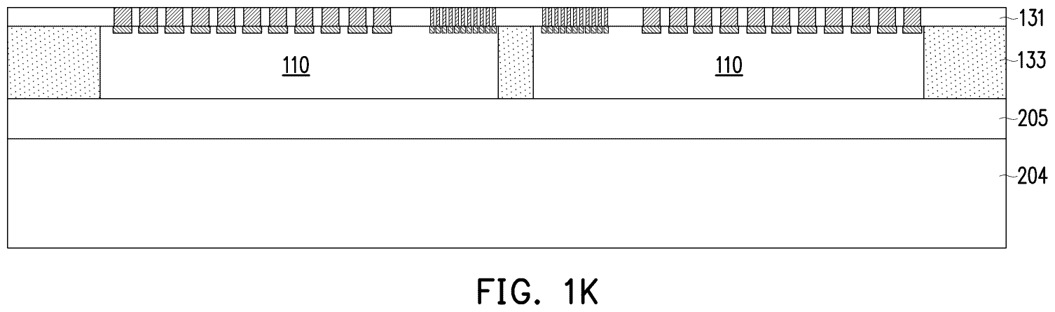

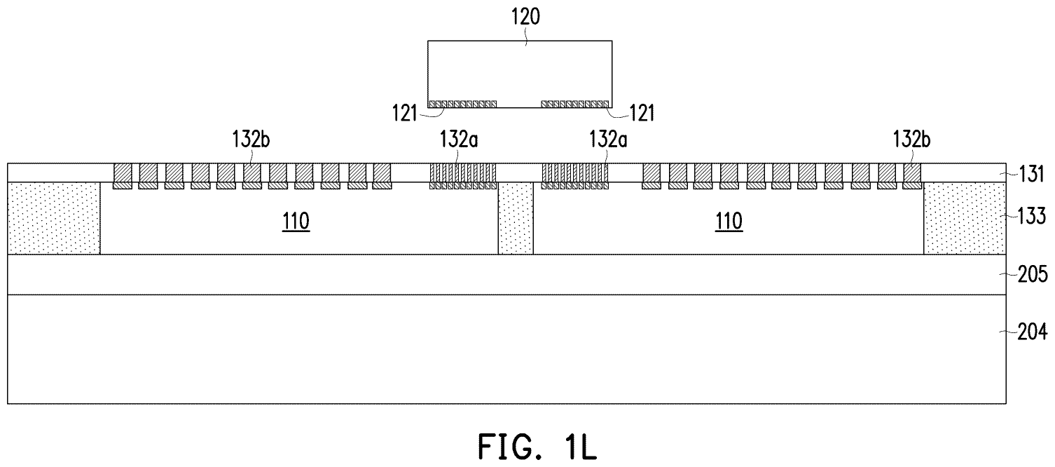

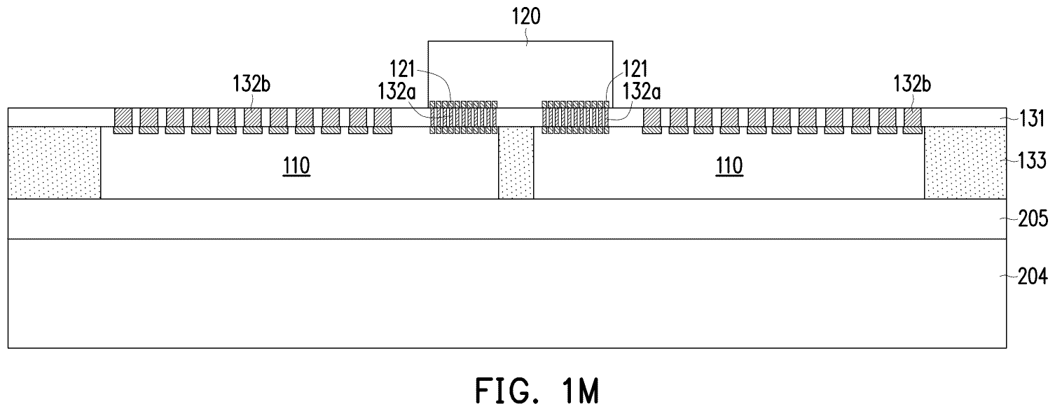

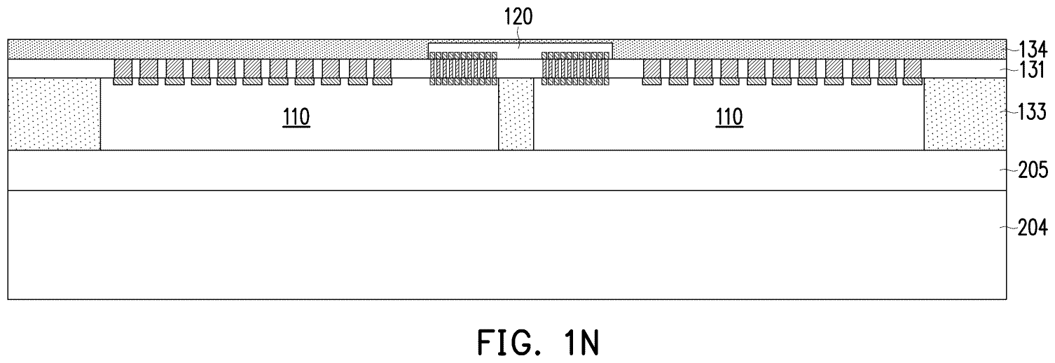

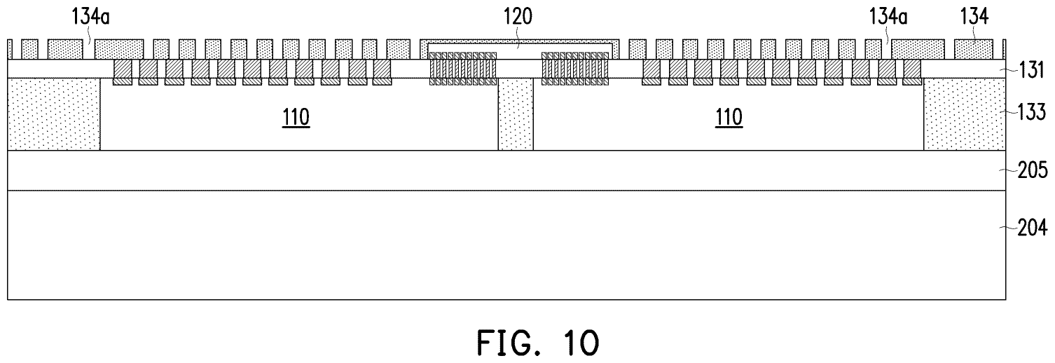

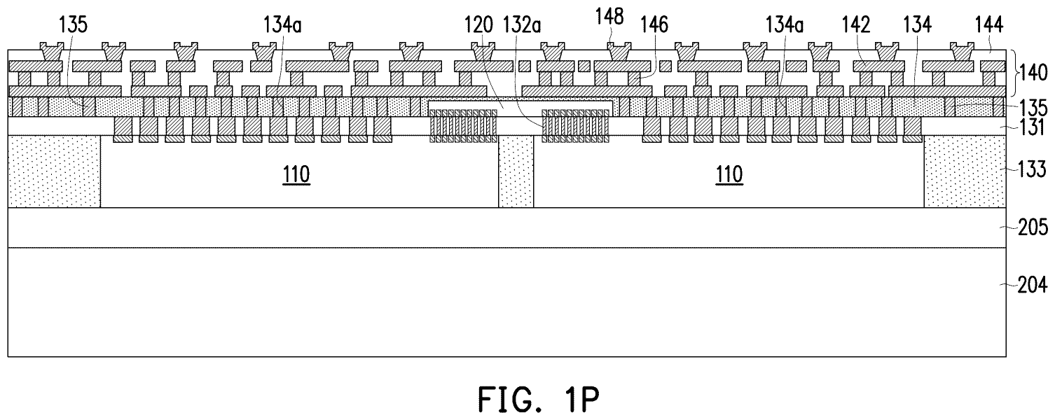

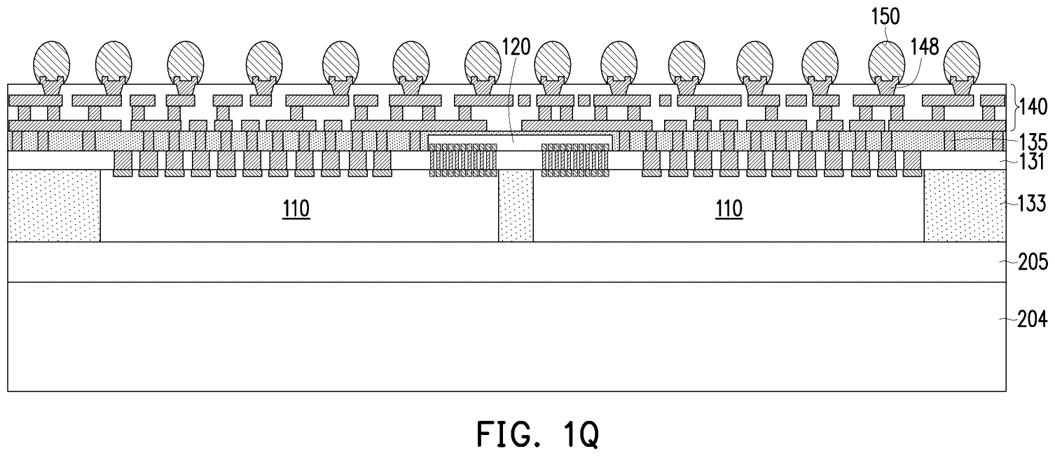

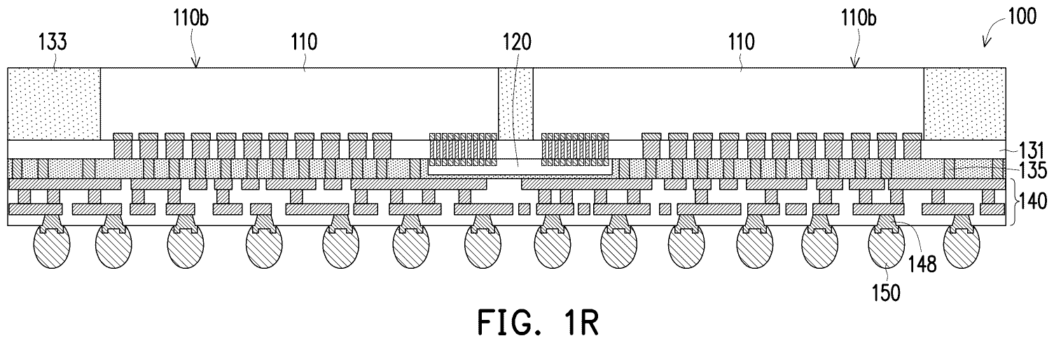

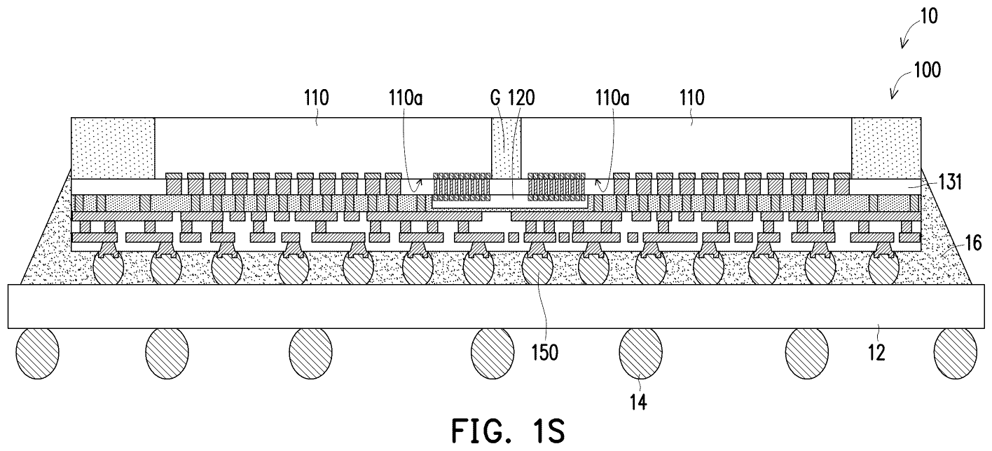

Reference will be made to FIGS. 1A to 1S to describe a manufacturing method of an electronic package in an embodiment of the disclosure.

Referring to FIG. 1A, a first temporary carrier 201 and a first temporary bonding layer 202 are provided. The first temporary bonding layer 202 is disposed on the first temporary carrier 201.

Referring to FIG. 1B, an etch stop layer 203 is formed on the first temporary bonding layer 202.

Referring to FIGS. 1C to 1F, a first interfacial dielectric layer 131, multiple first conductive vias 132a, and multiple second conductive vias 132b are formed on the etch stop layer 203. The first interfacial dielectric layer 131 covers the etch stop layer 203, the sides of the first conductive vias 132a, and the sides of the second conductive vias 132b. The details are as follows.

As shown in FIG. 1C, a first interfacial dielectric layer 131 is formed on the etch stop layer 203. The material of the first interfacial dielectric layer 131 is, for example, silicon carbonitride (SiCN), silicon nitride (SiN), silicon oxide (SiO), silicon oxynitride (SiON), silicon carbide (SiC), oxide, or polymer.

As shown in FIG. 1D, multiple portions of the first interfacial dielectric layer 131 are removed to form multiple first through holes 131a and multiple second through holes 131b. For example, the portions of the first interfacial dielectric layer 131 may be removed through a hard mask pattern along with anisotropic etching, or through a photolithography process for polymer dielectric materials.

As shown in FIG. 1E, conductive materials are filled in the first through holes 131a and the second through holes 131b to form the first conductive vias 132a and the second conductive vias 132b. For example, the formation of the first conductive vias 132a and the second conductive vias 132b may include forming a barrier layer and a seed layer (both not shown) through electroless plating or physical vapor deposition, followed by forming the conductive materials (e.g., copper) in the first through holes 131a and the second through holes 131b through electroplating, thereby forming the first conductive vias 132a and the second conductive vias 132b.

As shown in FIG. 1F, excess conductive materials, barrier layers, and seed layers on the first interfacial dielectric layer 131 may be respectively removed through metal etching and polishing (e.g., CMP), such that the first interfacial dielectric layer 131 covers the etch stop layer 203, the sides of the first conductive vias 132a, and the sides of the second conductive vias 132b.

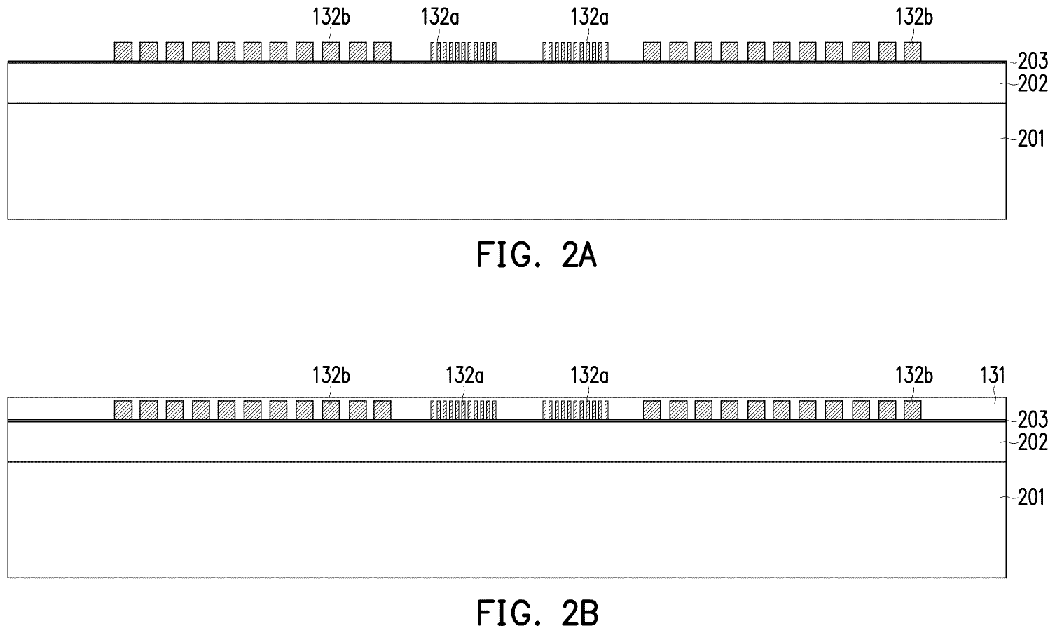

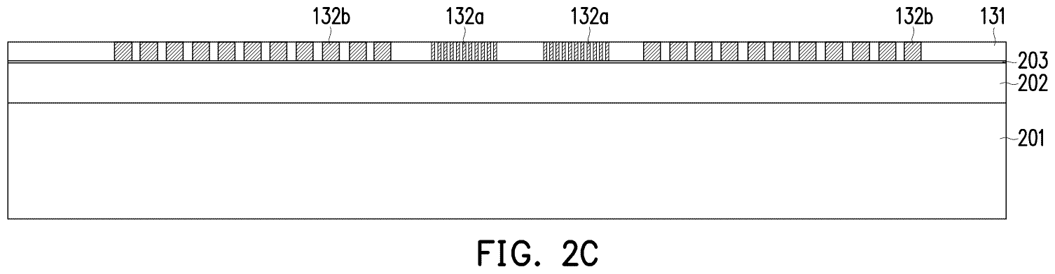

In other embodiments, in addition to the steps in FIGS. 1C to 1F, the first interfacial dielectric layer 131, the first conductive vias 132a, and the second conductive vias 132b may also be formed through the steps in FIGS. 2A to 2C. The description is provided below.

As shown in FIG. 2A, multiple first conductive vias 132a and multiple second conductive vias 132b may be formed on the etch stop layer 203. For example, the seed layer and a mask pattern (both not shown) are sequentially formed on the etch stop layer 203. Next, the conductive materials are electroplated, through the seed layer, into the through holes formed by the mask pattern so as to form the first conductive vias 132a and the second conductive vias 132b. Finally, the mask pattern and the seed layer are removed to expose the first conductive vias 132a and the second conductive vias 132b.

As shown in FIG. 2B, a first interfacial dielectric layer 131 that completely covers the etch stop layer 203, the first conductive vias 132a, and the second conductive vias 132b is formed.

As shown in FIG. 2C, a portion of the first interfacial dielectric layer 131 may be removed through polishing (e.g., CMP) to expose the top portions of the first conductive vias 132a and the second conductive vias 132b.

Referring to FIG. 1G, surface treatment is applied to the first conductive vias 132a and the second conductive vias 132b. At the same time, multiple chips 110 are provided. Multiple first chip pads 111 and multiple second chip pads 112 on an active surface 110a of each of the chips 110 are also pre-treated and ready for direct bonding.

Referring to FIG. 1H, the chips 110 are mounted on the first interfacial dielectric layer 131. The first chip pads 111 and the second chip pads 112 on the active surface 110a of each of the chips 110 are directly bonded to the first conductive vias 132a and the second conductive vias 132b respectively.

Referring to FIG. 1I, a base dielectric layer 133 is formed to cover the first interfacial dielectric layer 131 and the sides of the chips 110. The base dielectric layer 130 fills a gap G between the adjacent chips 110. For example, at a temperature of 200 degrees Celsius or below, a dielectric material such as oxide covers the first interfacial dielectric layer 131 as well as the active surfaces 110a and the sides of the chips 110 to form a base dielectric layer 133.

Referring to FIG. 1J, a first temporary carrier 201 and a first temporary bonding layer 202 shown in FIG. 1I are removed.

Referring to FIG. 1K, the chips 110 and the base dielectric layer 133 are fixed to a second temporary carrier 204 through a second temporary bonding layer 205. The etch stop layer 203 shown in FIG. 1J is removed.

Referring to FIG. 1L, surface treatment is applied to the first conductive vias 132a and the second conductive vias 132b. At the same time, a bridge element 120 is provided. Multiple bridge pads 121 are disposed on the bridge element 120 for the direct-bonding in the following steps.

Referring to FIG. 1M, the bridge element 120 is mounted on the first interfacial dielectric layer 131, such that the bridge element 120 partially overlaps the adjacent chips 110 respectively. The bridge pads 121 of the bridge element 120 are directly bonded to the first conductive vias 132a respectively.

Referring to FIGS. 1N to 1P, a second interfacial dielectric layer 134 and multiple third conductive vias 135 are formed on the first interfacial dielectric layer 131 and the bridge element 120. The third conductive vias 135 pass through the second interfacial dielectric layer 134 to be connected to the second conductive vias 132b respectively.

As shown in FIG. 1N, the second interfacial dielectric layer 134 is formed on the first interfacial dielectric layer 131 and the bridge element 120. In an embodiment, the bridge element 120 may be thinned before forming the second interfacial dielectric layer 134. In addition, at a temperature of 200 degrees Celsius or below, a dielectric material such as oxide covers the first interfacial dielectric layer 131 and the bridge element 120 to form the second interfacial dielectric layer 134.

As shown in FIG. 1O, multiple portions of the second interfacial dielectric layer 134 are removed to form multiple third through holes 134a. For example, the portions of the second interfacial dielectric layer 134 may be removed through a photolithography process, laser drilling, or a hard mask pattern along with dielectric etching.

As shown in FIG. 1P, conductive materials are filled in the third through holes 134a to form the third conductive vias 135. For example, the third conductive vias 135 may be formed in the same method as the first conductive vias 132a and the second conductive vias 132b (as shown in FIG. 1F).

Referring to FIG. 1P again, a redistribution circuit structure 140 is formed on the second interfacial dielectric layer 134 and the third conductive vias 135. In this embodiment, the redistribution circuit structure 140 may be formed through a build-up process. The redistribution circuit structure 140 includes multiple redistribution patterned conductive layers 142, multiple redistribution dielectric layers 144, and multiple redistribution conductive vias 146. The redistribution patterned conductive layers 142 and the redistribution dielectric layers 144 are alternately stacked. The redistribution conductive vias 146 are connected to the redistribution patterned conductive layers 142 respectively. In addition, multiple under bump metallurgy (UBM) layers 148 are formed on the portions of one of the redistribution patterned conductive layers 142 farthest from the chips 110. In an embodiment, conductive materials may be filled in the third through holes 134a in the second interfacial dielectric layer 134 during the formation of the redistribution circuit structure 140 so as to form the third conductive vias 135.

Referring to FIG. 1Q, multiple conductive bumps 150 are formed on the redistribution circuit structure 140. In this embodiment, the conductive bumps 150 are respectively formed on the UBM layers 148 of the redistribution circuit structure 140.

Referring to FIG. 1R, the second temporary bonding layer 205 and the second temporary carrier 204 shown in FIG. 1Q are removed to expose a back surface 110b of each of the chips 110. This completes the formation of a sub-package 100.

Referring to FIG. 1S, the conductive bumps 150 are connected to a circuit carrier 12. Multiple conductive balls 14 are also connected to the circuit carrier 12. In this embodiment, after the conductive bumps 150 are connected to the circuit carrier 12, an underfill 16 is filled in a space between the sub-package 100 and the circuit carrier 12 and encapsulates the conductive bumps 150. This completes the formation of the electronic package 10.

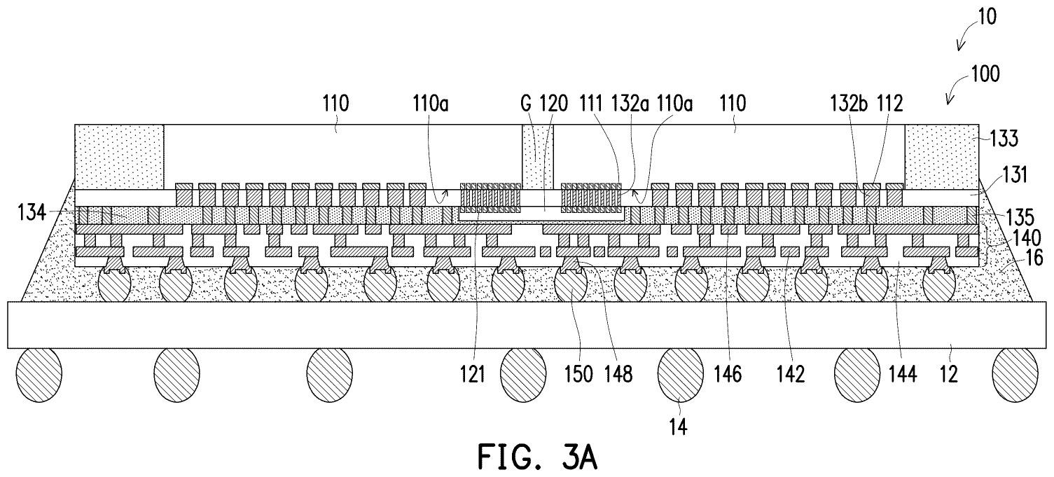

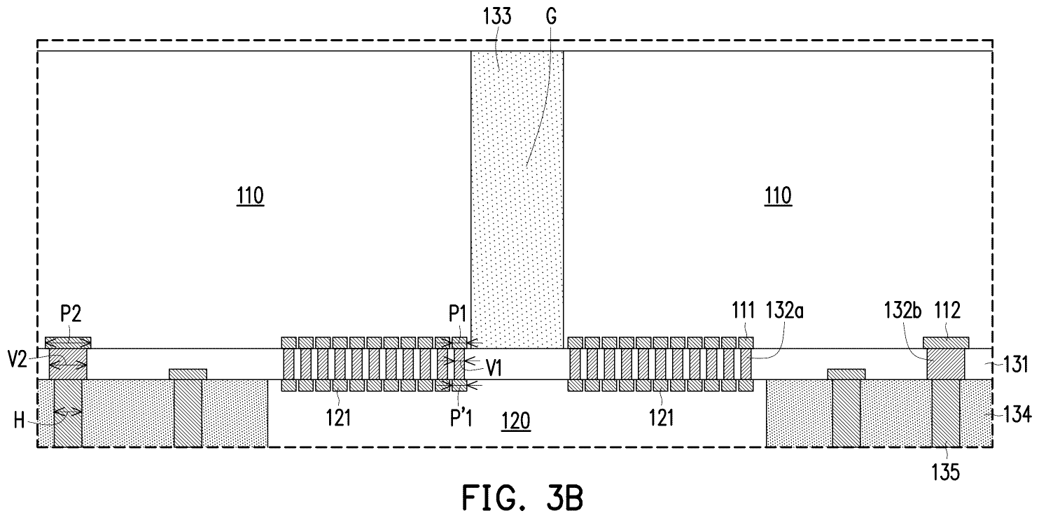

Reference will be made to FIGS. 3A and 3B to describe a manufacturing method of an electronic package 10 in an embodiment of the disclosure. The electronic package 10 may be produced through the manufacturing method in the above-mentioned embodiments or other manufacturing methods.

Referring to FIGS. 3A and 3B, in this embodiment, the electronic package 10 includes one or more sub-packages 100. Only one sub-package 100 is used for example in FIG. 3A.

The sub-package 100 includes multiple chips 110, multiple first conductive vias 132a, multiple second conductive vias 132b, and a first interfacial dielectric layer 131. The chips 110 are arranged in a plane. An active surface 110a of each of the chips 110 has multiple first chip pads 111 and multiple second chip pads 112. The first conductive vias 132a are directly bonded to the first chip pads 111 respectively. The second conductive vias 132b are directly bonded to the second chip pads 112 respectively. The first interfacial dielectric layer 131 covers the sides of the first conductive vias 132a and the sides of the second conductive vias 132b.

The sub-package 100 further includes at least one bridge element 120, a second interfacial dielectric layer 134, and multiple third conductive vias 135. The bridge element 120 partially overlaps the adjacent chips 110 respectively. Multiple bridge pads 121 of the bridge element 120 are directly bonded to the first conductive vias 132a respectively. The second interfacial dielectric layer 134 is located on the first interfacial dielectric layer 131 and the bridge element 120. The third conductive vias 135 pass through the second interfacial dielectric layer 134 to be connected to the second conductive vias 132b respectively. Notably, an outer diameter H of the third conductive via 135 is smaller than an outer diameter P2 of the second chip pad 112.

The sub-package 100 further includes a redistribution circuit structure 140 and multiple conductive bumps 150. The redistribution circuit structure 140 is disposed on the second interfacial dielectric layer 134 and the third conductive vias 135. The conductive bumps 150 are disposed on the redistribution circuit structure 140.

In this embodiment, as shown in FIG. 3B, an outer diameter V1 of the first conductive via 132a is smaller than an outer diameter P1 of the first chip pad 111 connected to the first conductive via 132a. The outer diameter V1 of the first conductive via 132a may also be smaller than an outer diameter P′1 of the bridge pad 121 connected to the first conductive via 132a. An outer diameter V2 of the second conductive via 132b is smaller than the outer diameter P2 of the second chip pad 112, and the outer diameter H of the third conductive via 135 is smaller than the outer diameter V2 of the second conductive via 132b.

In this embodiment, a distribution density of the first chip pads 111 is greater than a distribution density of the second chip pads 112. A distribution density means the amount of the chip pads in a specific area. One of the chips 110 may be a central processing unit chip, a logic chip, a graphics processing unit chip, an input/output chip, a memory chip, a baseband chip, a radio frequency chip, or a special purpose integrated circuit chip.

In this embodiment, a thickness of the bridge element 120 may be smaller than a thickness of the chip 110 to reduce a thickness of the entire electronic package 10. The bridge element 120 may be an active element or a passive element.

In this embodiment, the sub-package 100 may further include a base dielectric layer 133. The base dielectric layer 133 covers the first interfacial dielectric layer 131 and the sides of the chips 110. The base dielectric layer 133 also fills the gap G between the adjacent chips 110.

In this embodiment, the electronic package 10 includes a circuit carrier 12. The sub-package 100 is mounted on the circuit carrier 12. In addition, the electronic package 10 may further include multiple conductive balls 14. The conductive balls 14 are connected to the circuit carrier 12. Furthermore, the electronic package 10 includes an underfill 16. The underfill 16 is filled in a space between the redistribution circuit structure 140 and the circuit carrier 12 and encapsulates the conductive bumps 150.

In this embodiment, by bonding the first chip pad 111 and the bridge pad 121 with the first conductive via 132a only (it means direct bonding), the chips 110 are electrically connected to the bridge element 120, and the chips 110 transmit signals to each other through the first conductive via 132a and the bridge element 120. In addition, by bonding the second chip pad 112 and the third conductive via 135 with the second conductive via 132b only (it means direct bonding), the corresponding chip 110 is electrically connected to the redistribution circuit structure 140, and the corresponding chip 110 transmits signals through the second conductive via 132b, the third conductive via 135, and the redistribution circuit structure 140. With the direct bonding, the problem of chip misalignment caused by the use of molding compound between the chips and bridge elements can be solved.

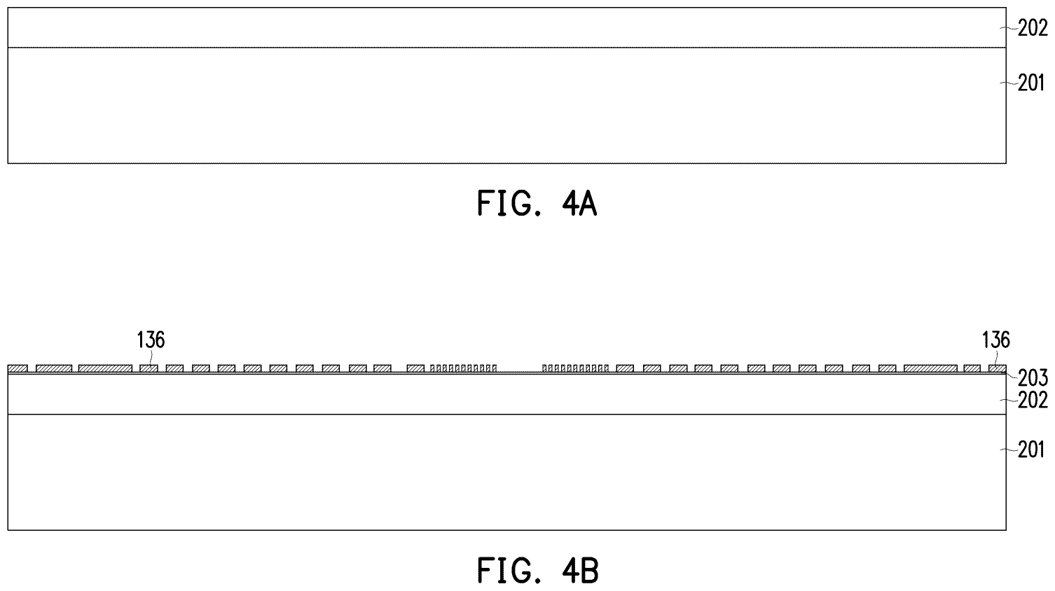

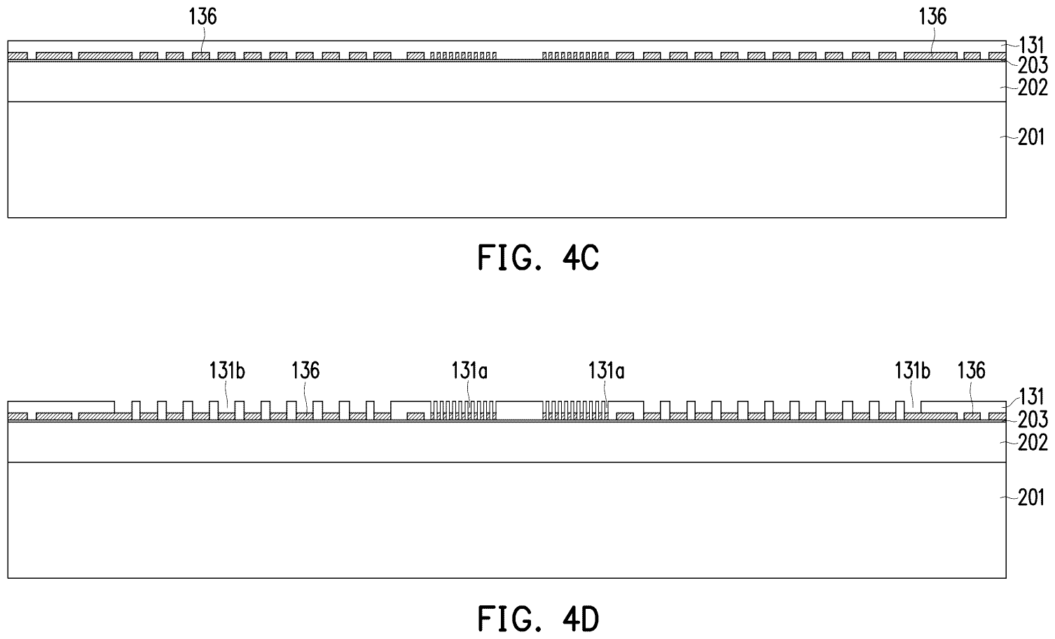

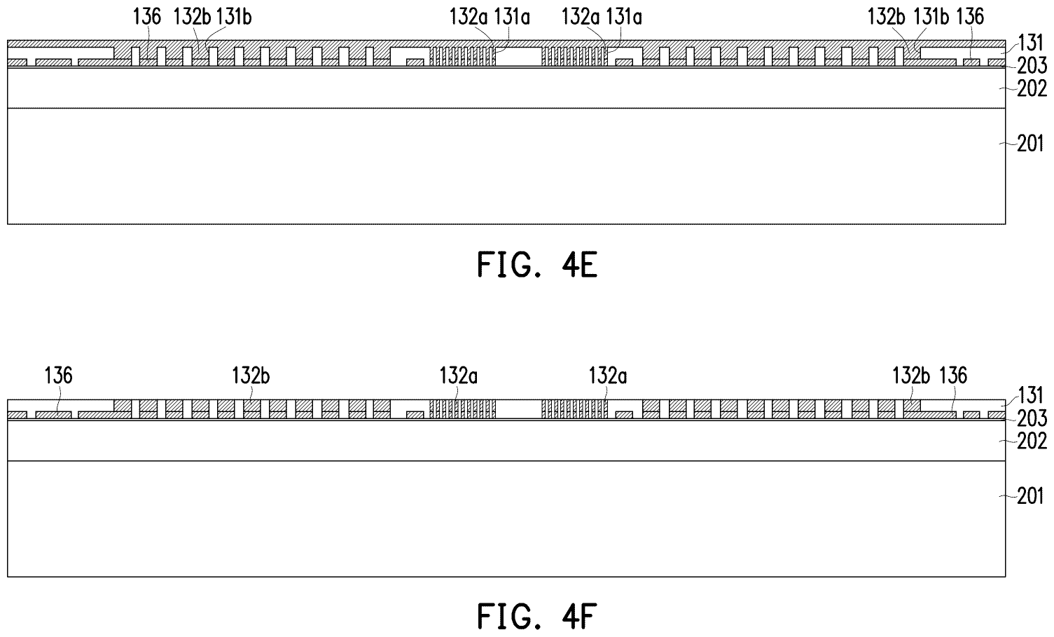

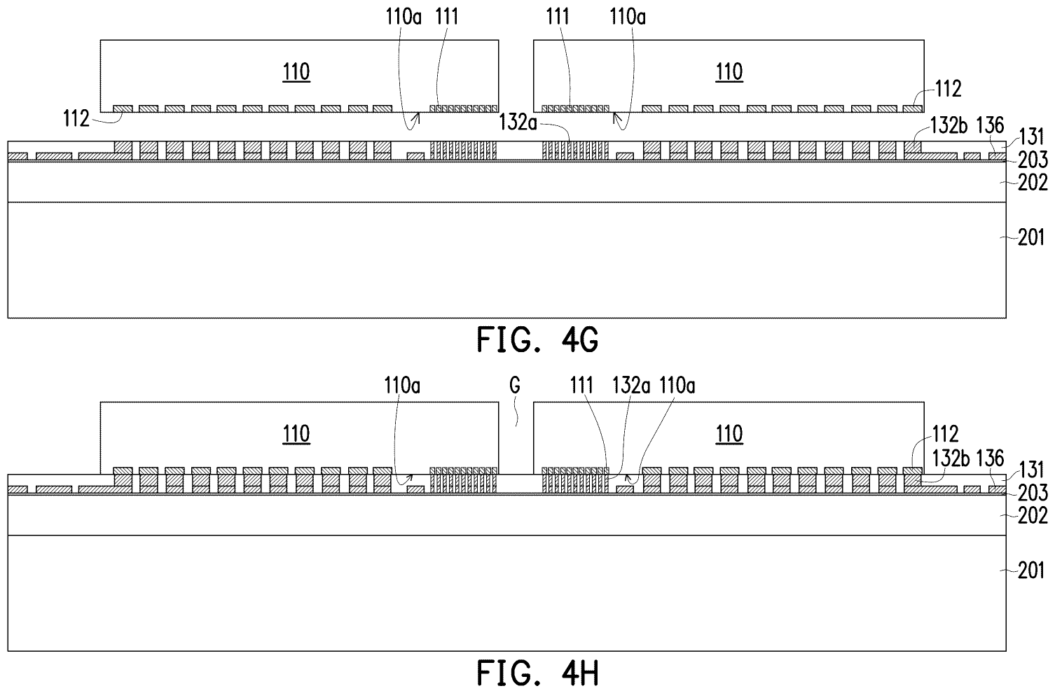

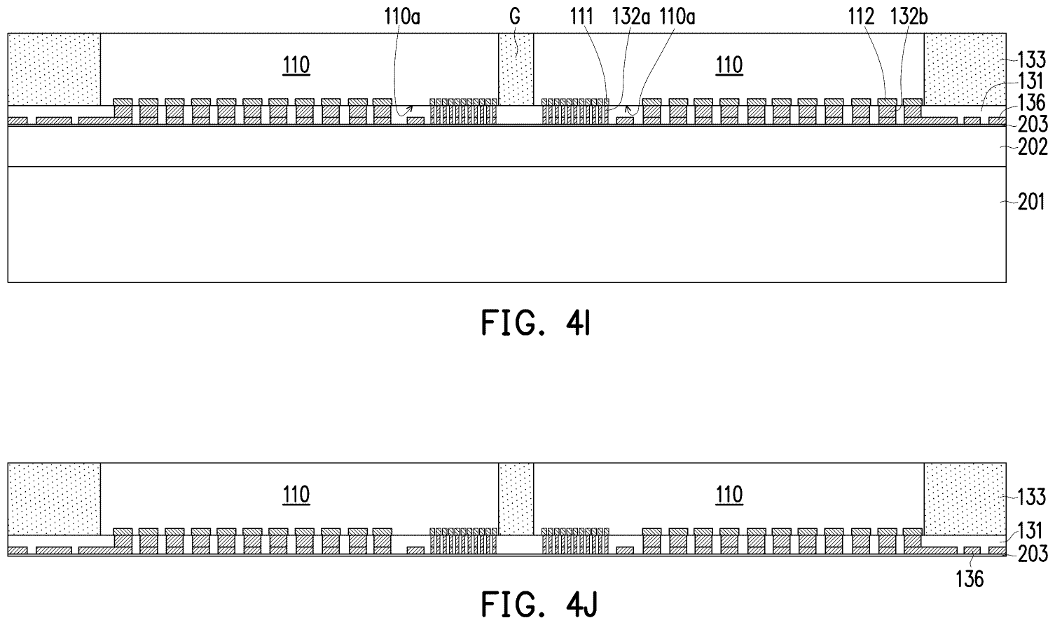

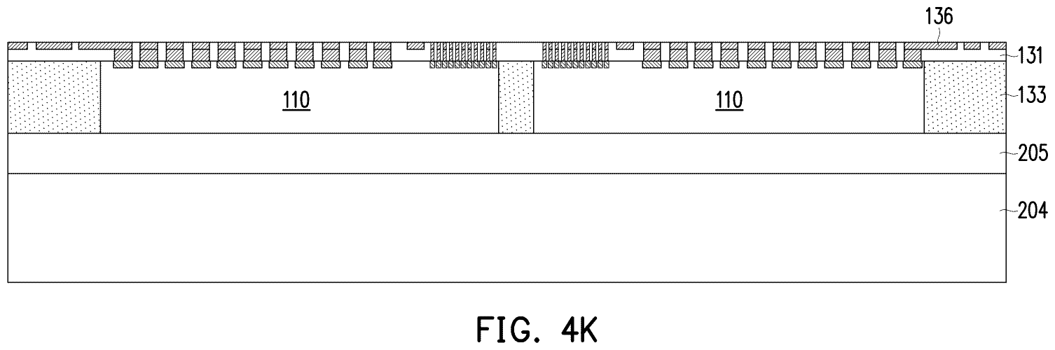

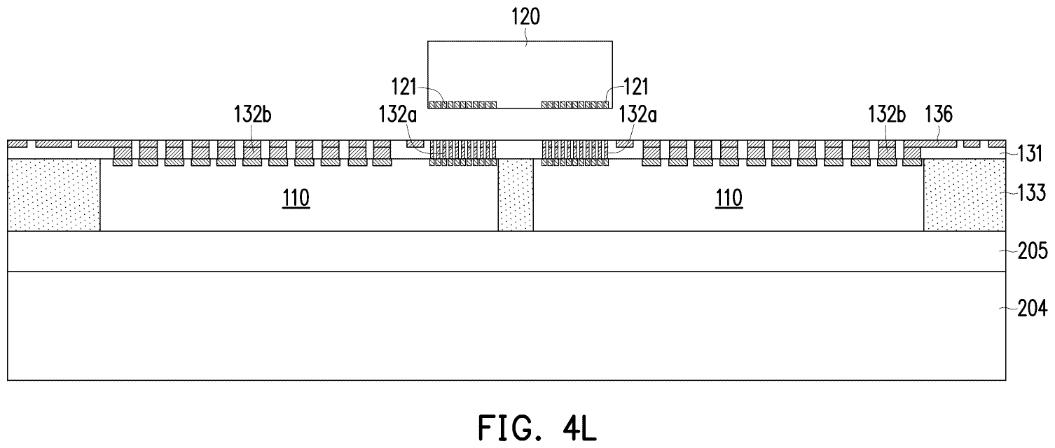

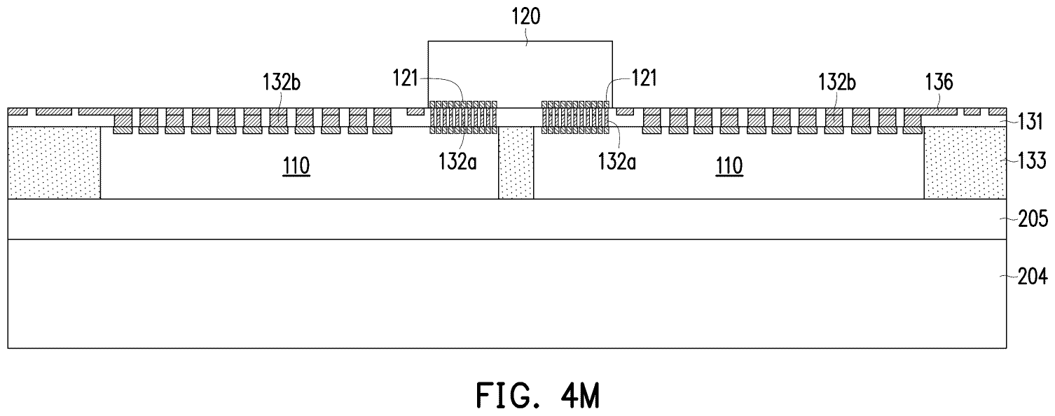

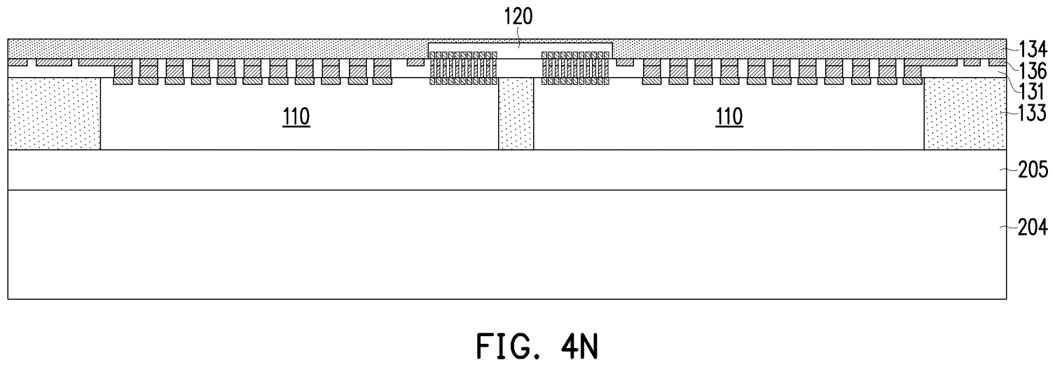

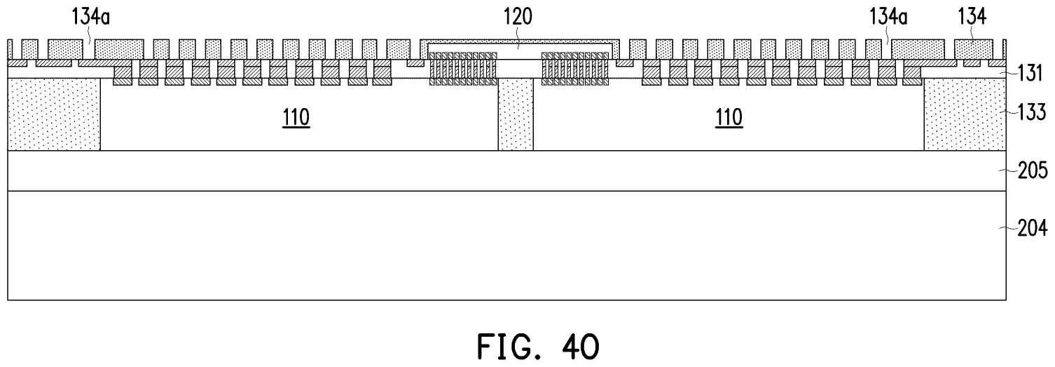

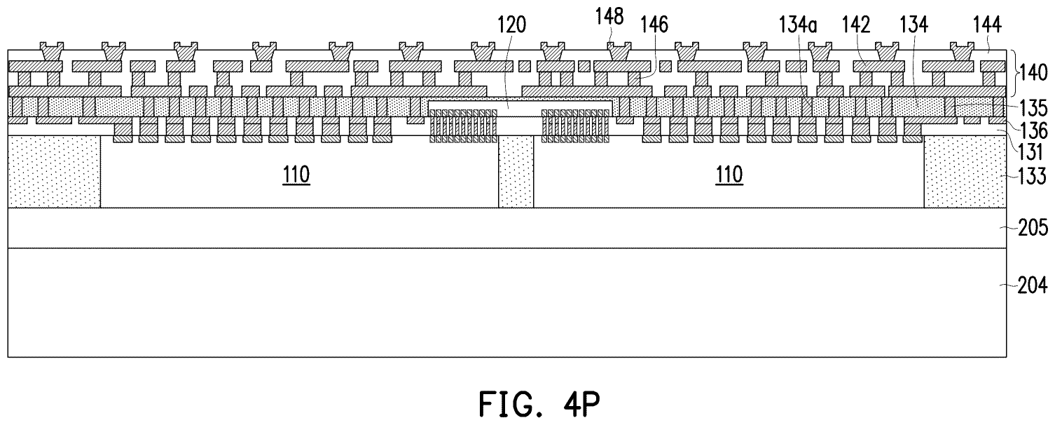

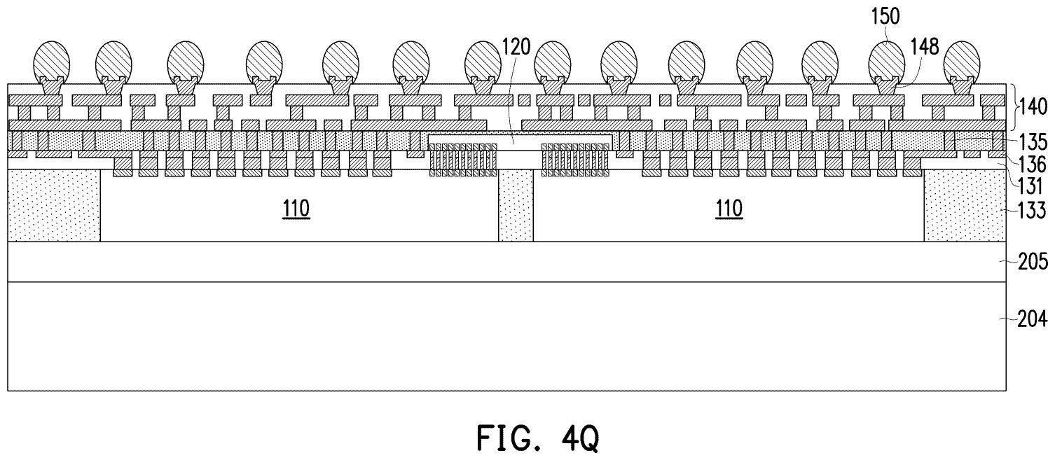

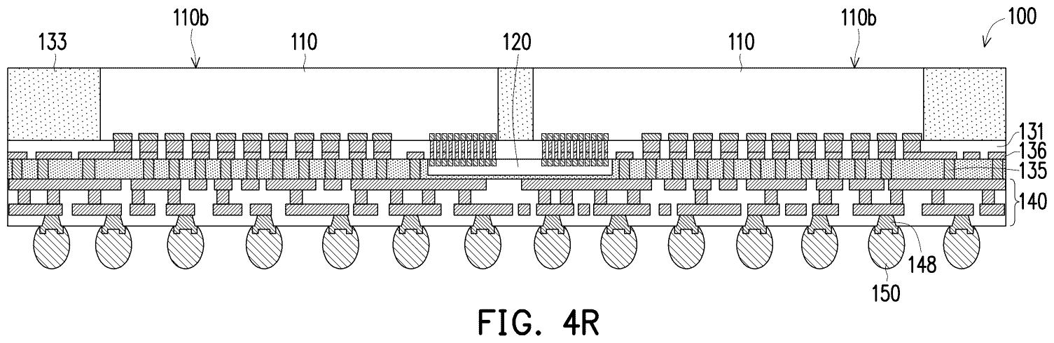

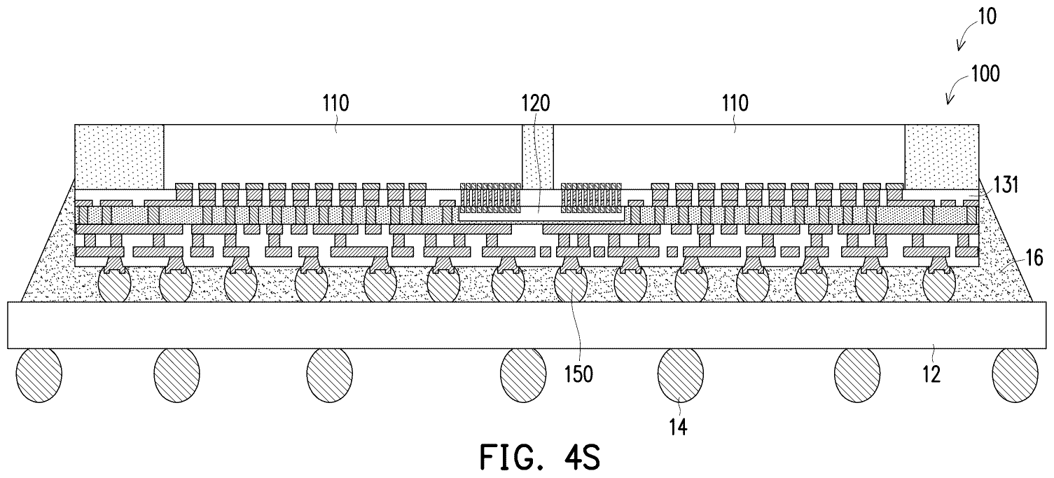

Reference will be made to FIGS. 4A to 4S to describe a manufacturing method of an electronic package 10 in another embodiment of the disclosure.

Referring to FIG. 4A, a first temporary carrier 201 and a first temporary bonding layer 202 are provided. The first temporary bonding layer 202 is disposed on the first temporary carrier 201.

Referring to FIG. 4B, an etch stop layer 203 and a fan-out circuit layer 136 are formed on the first temporary bonding layer 202. For example, the etch stop layer 203 is formed on the first temporary bonding layer 202 first. Next, the fan-out circuit layer 136 is formed on the etch stop layer 203. The formation of the fan-out circuit layer 136 may include forming a barrier layer and a seed layer (both not shown) through electroless plating or physical vapor deposition (PVD), followed by forming the conductive materials (e.g., copper) on the etch stop layer 203 through electroplating, thereby forming the fan-out circuit layer 136.

Referring to FIGS. 4C to 4F, a first interfacial dielectric layer 131, multiple first conductive vias 132a, and multiple second conductive vias 132b are formed on the etch stop layer 203 and the fan-out circuit layer 136. The first interfacial dielectric layer 131 covers the etch stop layer 203, the sides of the first conductive vias 132a, and the sides of the second conductive vias 132b. The first conductive vias 132a and the second conductive vias 132b are respectively connected to the fan-out circuit layer 136. The details are as follows.

As shown in FIG. 4C, a first interfacial dielectric layer 131 is formed on the etch stop layer 203. The first interfacial dielectric layer 131 covers the fan-out circuit layer 136. The material of the first interfacial dielectric layer 131 is, for example, silicon carbonitride (SiCN), silicon nitride (SiN), silicon oxide (SiO), silicon oxynitride (SiON), silicon carbide (SiC), oxide, or polymer.

As shown in FIG. 4D, multiple portions of the first interfacial dielectric layer 131 are removed to form multiple first through holes 131a and multiple second through holes 131b. For example, the portions of the first interfacial dielectric layer 131 may be removed through a hard mask pattern along with anisotropic etching, or through a photolithography process for polymer dielectric materials.

As shown in FIG. 4E, conductive materials are filled in the first through holes 131a and the second through holes 131b to form the first conductive vias 132a and the second conductive vias 132b, and the first conductive vias 132a and the second conductive vias 132b are connected to the fan-out circuit layer 136 respectively. For example, the formation of the first conductive vias 132a and the second conductive vias 132b may include forming a barrier layer and a seed layer (both not shown) through electroless plating or physical vapor deposition, followed by forming the conductive materials (e.g., copper) in the first through holes 131a and the second through holes 131b through electroplating, thereby forming the first conductive vias 132a and the second conductive vias 132b.

As shown in FIG. 4F, excess conductive materials, barrier layers, and seed layers on the first interfacial dielectric layer 131 may be respectively removed through metal etching and polishing (e.g., CMP), such that the first interfacial dielectric layer 131 covers the etch stop layer 203, the fan-out circuit layer 136, the sides of the first conductive vias 132a, and the sides of the second conductive vias 132b.

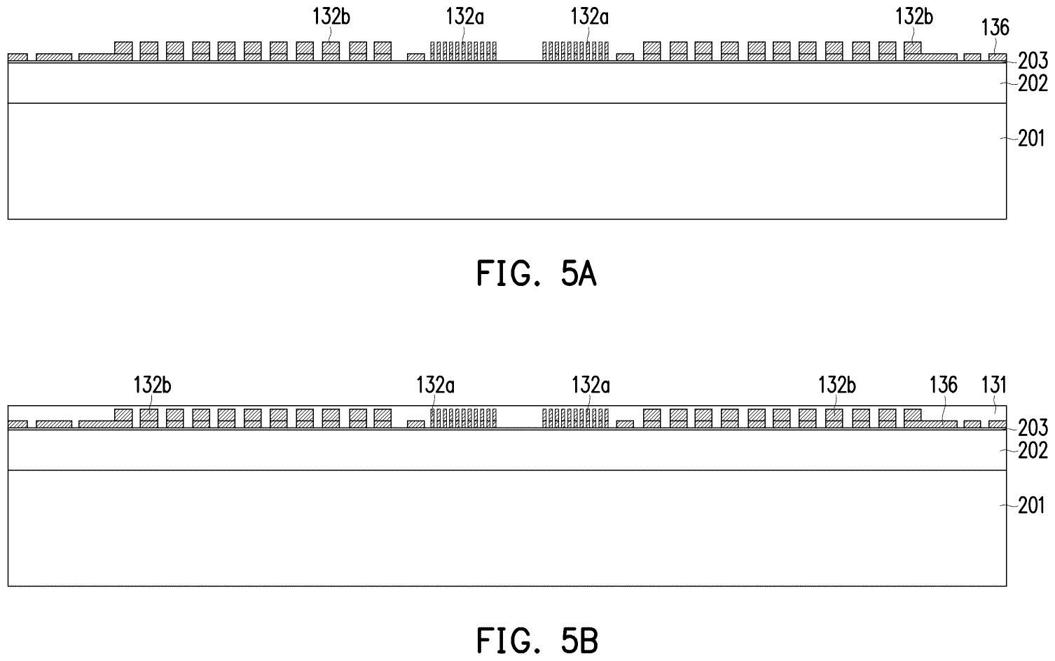

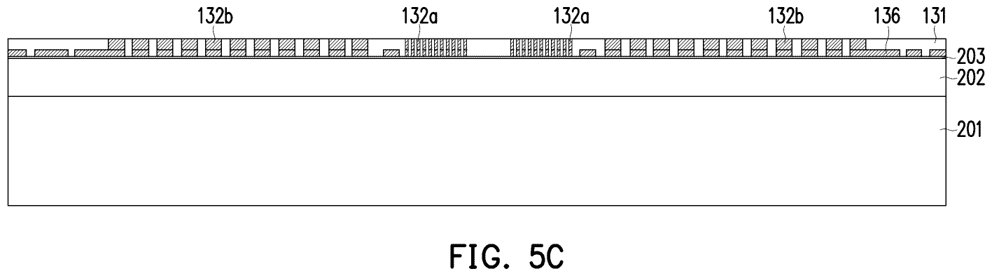

In addition to the steps in FIGS. 4C to 4F, the first interfacial dielectric layer 131, the first conductive vias 132a, and the second conductive vias 132b may also be formed through the steps in FIGS. 5A and 5C.

As shown in FIG. 5A, a fan-out circuit layer 136, multiple first conductive vias 132a, and multiple second conductive vias 132b may be formed on the etch stop layer 203. For example, the fan-out circuit layer 136 is formed on the etch stop layer 203 first. Next, the first conductive vias 132a and the second conductive vias 132b are formed on the fan-out circuit layer 136. In addition, the seed layer and the mask pattern (both not shown) are sequentially formed on the etch stop layer 203 and the fan-out circuit layer 136. Next, the conductive materials are electroplated, through the seed layer, into the through holes formed by the mask pattern so as to form the first conductive vias 132a and the second conductive vias 132b. Finally, the mask pattern and the seed layer are removed to expose the fan-out circuit layer 136, the first conductive vias 132a, and the second conductive vias 132b.

As shown in FIG. 5B, a first interfacial dielectric layer 131 that completely covers the etch stop layer 203, the fan-out circuit layer 136, the first conductive vias 132a, and the second conductive vias 132b is formed.

As shown in FIG. 5C, a portion of the first interfacial dielectric layer 131 may be removed through polishing (e.g., CMP) to expose the first conductive vias 132a and the second conductive vias 132b.

Referring to FIG. 4G, surface treatment is applied to the first conductive vias 132a and the second conductive vias 132b. At the same time, multiple chips 110 are provided. Multiple first chip pads 111 and multiple second chip pads 112 on an active surface 110a of each of the chips 110 are also pre-treated and ready for direct bonding. In addition, orthogonal projections of the chips 110 are located in the fan-out circuit layer 136. That is, an area of a region occupied by the fan-out circuit layer 136 is greater than an orthogonal projection area of the chips 110.

Referring to FIG. 4H, the chips 110 are mounted on the first interfacial dielectric layer 131. The first chip pads 111 and the second chip pads 112 on the active surface 110a of each of the chips 110 are directly bonded to the first conductive vias 132a and the second conductive vias 132b respectively.

Referring to FIG. 4I, a base dielectric layer 133 is formed to cover the first interfacial dielectric layer 131 and the sides of the chips 110. The base dielectric layer 130 fills a gap G between the adjacent chips 110. For example, at a temperature of 200 degrees Celsius or below, a dielectric material such as oxide covers the first interfacial dielectric layer 131 as well as the active surfaces 110a and the sides of the chips 110 to form the base dielectric layer 133.

Referring to FIG. 4J, the first temporary carrier 201 and the first temporary bonding layer 202 shown in FIG. 4I are removed.

Referring to FIG. 4K, the chips 110 and the base dielectric layer 133 are fixed to the second temporary carrier 204 through the second temporary bonding layer 205. The etch stop layer 203 shown in FIG. 4J is removed.

Referring to FIG. 4L, surface treatment is applied to the first conductive vias 132a and the second conductive vias 132b. At the same time, a bridge element 120 is provided. Multiple bridge pads 121 are disposed on the bridge element 120 for the direct-bonding in the following steps. In this embodiment, the portions of the fan-out circuit layer 136 respectively connected to the first conductive vias 132a and the second conductive vias 132b may be deemed the physical extensions of the first conductive vias 132a and the second conductive vias 132b. Therefore, performing surface treatment on the first conductive vias 132a and the second conductive vias 132b refers to performing surface treatment on the portions of the fan-out circuit layer 136 respectively connected to the first conductive vias 132a and the second conductive vias 132b.

Referring to FIG. 4M, the bridge element 120 is mounted on the first interfacial dielectric layer 131, such that the bridge element 120 partially overlaps the adjacent chips 110 respectively. The bridge pads 121 of the bridge element 120 are directly bonded to the first conductive vias 132a respectively.

Referring to FIGS. 4N to 4P, a second interfacial dielectric layer 134 and multiple third conductive vias 135 are formed on the first interfacial dielectric layer 131 and the bridge element 120. The third conductive vias 135 pass through the second interfacial dielectric layer 134 to be connected to the second conductive vias 132b respectively.

As shown in FIG. 4N, the second interfacial dielectric layer 134 is formed on the first interfacial dielectric layer 131 and the bridge element 120. In an embodiment, the bridge element 120 may be thinned before forming the second interfacial dielectric layer 134. In addition, at a temperature of 200 degrees Celsius or below, a dielectric material such as oxide covers the first interfacial dielectric layer 131 and the bridge element 120 to form the second interfacial dielectric layer 134.

As shown in FIG. 4O, multiple portions of the second interfacial dielectric layer 134 are removed to form multiple third through holes 134a. For example, the portions of the second interfacial dielectric layer 134 may be removed through a photolithography process, laser drilling, or a hard mask pattern along with dielectric etching.

As shown in FIG. 4P, conductive materials are filled in the third through holes 134a to form the third conductive vias 135. For example, the third conductive vias 135 may be formed in the same method as the first conductive vias 132a and the second conductive vias 132b (as shown in FIG. 4F).

Referring to FIG. 4P again, a redistribution circuit structure 140 is formed on the second interfacial dielectric layer 134 and the third conductive vias 135. In this embodiment, the redistribution circuit structure 140 may be formed through a build-up process. The redistribution circuit structure 140 includes multiple redistribution patterned conductive layers 142, multiple redistribution dielectric layers 144, and multiple redistribution conductive vias 146. The redistribution patterned conductive layers 142 and the redistribution dielectric layers 144 are alternately stacked. The redistribution conductive vias 146 are connected to the redistribution patterned conductive layers 142 respectively. In addition, multiple UBM layers 148 are formed on the portions of one of the redistribution patterned conductive layers 142 farthest from the chips 110. In an embodiment, conductive materials may be filled in the third through holes 134a in the second interfacial dielectric layer 134 during the formation of the redistribution circuit structure 140 so as to form the third conductive vias 135.

Referring to FIG. 4Q, multiple conductive bumps 150 are formed on the redistribution circuit structure 140. In this embodiment, the conductive bumps 150 are respectively formed on the UBM layers 148 of the redistribution circuit structure 140.

Referring to FIG. 4R, the second temporary bonding layer 205 and the second temporary carrier 204 shown in FIG. 4Q are removed to expose the back surface 110b of each of the chips 110. This completes the formation of the sub-package 100.

Referring to FIG. 4S, the conductive bumps 150 are connected to a circuit carrier 12. Multiple conductive balls 14 are also connected to the circuit carrier 12. In this embodiment, after the conductive bumps 150 are connected to the circuit carrier 12, the underfill 16 is filled in a space between the sub-package 100 and the circuit carrier 12 and encapsulates the conductive bumps 150. This completes the formation of the electronic package 10.

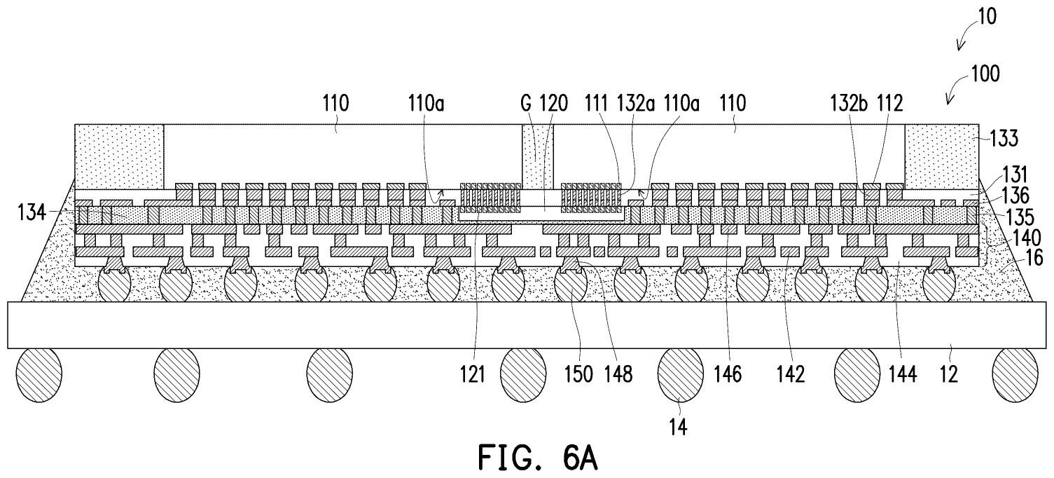

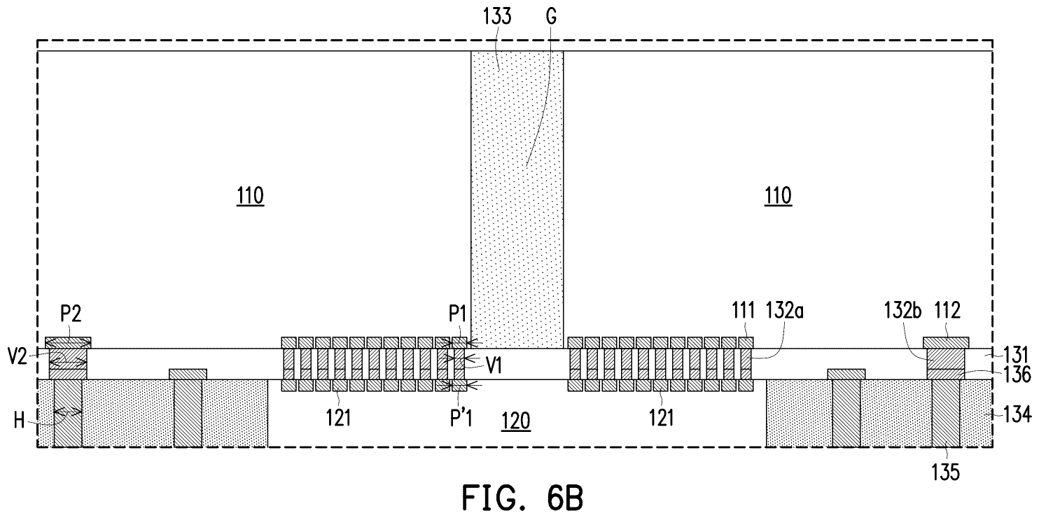

Reference will be made to FIGS. 6A and 6B to describe a manufacturing method of an electronic package 10 in an embodiment of the disclosure. The electronic package 10 may be produced through the manufacturing method in the above-mentioned embodiments or other manufacturing methods.

Referring to FIGS. 6A and 6B, in this embodiment, the electronic package 10 includes one or more sub-packages 100. Only one sub-package 100 is used for example in FIG. 6A.

The sub-package 100 includes multiple chips 110, multiple first conductive vias 132a, multiple second conductive vias 132b, a first interfacial dielectric layer 131, and a fan-out circuit layer 136. The chips 110 are arranged in a plane. An active surface 110a of each of the chips 110 has multiple first chip pads 111 and multiple second chip pads 112. The first conductive vias 132a are directly bonded to the first chip pads 111 respectively. The second conductive vias 132b are directly bonded to the second chip pads 112 respectively. The first interfacial dielectric layer 131 covers the active surfaces 110a of the chips 110, the sides of the first conductive vias 132a, and the sides of the second conductive vias 132b. The fan-out circuit layer 136 is embedded in the first interfacial dielectric layer 131 and connected to the first conductive vias 132a and the second conductive vias 132b. In addition, orthogonal projections of the chips 110 are located in the fan-out circuit layer 136. That is, an area of a region occupied by the fan-out circuit layer 136 is greater than an orthogonal projection area of the chips 110.

The sub-package 100 further includes at least one bridge element 120, a second interfacial dielectric layer 134, and multiple third conductive vias 135. The bridge element 120 partially overlaps the adjacent chips 110 respectively. Multiple bridge pads 121 of the bridge element 120 are directly bonded to the first conductive vias 132a respectively. The second interfacial dielectric layer 134 is located on the first interfacial dielectric layer 131 and the bridge element 120. The third conductive vias 135 pass through the second interfacial dielectric layer 134 to be connected to the second conductive vias 132b respectively. Notably, an outer diameter H of the third conductive via 135 is smaller than an outer diameter P2 of the second chip pad 112.

The sub-package 100 further includes a redistribution circuit structure 140 and multiple conductive bumps 150. The redistribution circuit structure 140 is disposed on the second interfacial dielectric layer 134 and the third conductive vias 135. The conductive bumps 150 are disposed on the redistribution circuit structure 140.

In this embodiment, as shown in FIG. 6B, an outer diameter V1 of the first conductive via 132a is smaller than an outer diameter P1 of the first chip pad 111 connected to the first conductive via 132a. The outer diameter V1 of the first conductive via 132a may also be smaller than an outer diameter P′1 of the bridge pad 121 connected to the first conductive via 132a. An outer diameter V2 of the second conductive via 132b is smaller than the outer diameter P2 of the second chip pad 112, and the outer diameter H of the third conductive via 135 is smaller than the outer diameter V2 of the second conductive via 132b.

In this embodiment, a distribution density of the first chip pads 111 is greater than a distribution density of the second chip pads 112. A distribution density means the amount of the chip pads in a specific area. One of the chips 110 may be a central processing unit chip, a logic chip, a graphics processing unit chip, an input/output chip, a memory chip, a baseband chip, a radio frequency chip, or a special purpose integrated circuit chip.

In this embodiment, a thickness of the bridge element 120 may be smaller than a thickness of the chip 110 to reduce a thickness of the entire electronic package 10. The bridge element 120 may be an active element or a passive element.

In this embodiment, the sub-package 100 may further include a base dielectric layer 133. The base dielectric layer 133 covers the first interfacial dielectric layer 131 and the sides of the chips 110. The base dielectric layer 133 also fills the gap G between the adjacent chips 110.

In this embodiment, the electronic package 10 includes a circuit carrier 12. The sub-package 100 is mounted on the circuit carrier 12. In addition, the electronic package 10 may further include multiple conductive balls 14. The conductive balls 14 are connected to the circuit carrier 12. Furthermore, the electronic package 10 includes an underfill 16. The underfill 16 is filled in a space between the redistribution circuit structure 140 and the circuit carrier 12 and encapsulates the conductive bumps 150.

In summary, in the above embodiments, the bridge element is bonded to the chips through the first conductive vias located in the first interfacial dielectric layer in case of direct bonding, and the chips transmit signals to each other through the first conductive via and the bridge element. In addition, the chips are electrically connected to a redistribution circuit layer through the second conductive via located in the first interfacial dielectric layer and the third conductive via located in the second interfacial dielectric layer, and the corresponding chip transmits signals through the second conductive via, the third conductive via, and the redistribution circuit structure. In addition, a fan-out circuit layer may be formed in the first interfacial dielectric layer so that a signal from the chip pad can be electrically extended from the active surface of the chip to a space outside the orthogonal projection area of the active surface of the chip, thereby enhancing the flexibility of circuit layout.

Moreover, in the above embodiments, as the bridge element is not bonded to the chip through the redistribution circuit layer, an electrical distance between the bridge element and the chip is reduced. Further, by not using micro bumps containing solder for bonding, adverse impacts such as parasitic capacitance and parasitic inductance are reduced, which facilitates a decrease in power consumption and an increase in applications in high-efficiency computing.

What is claimed is:

1. A manufacturing method of an electronic package, comprising:
forming a first interfacial dielectric layer, a plurality of first conductive vias, and a plurality of second conductive vias on a first temporary carrier, wherein the first interfacial dielectric layer covers the first temporary carrier, sides of the plurality of first conductive vias, and sides of the plurality of second conductive vias;
disposing a plurality of chips on the first interfacial dielectric layer, wherein a plurality of first chip pads and a plurality of second chip pads on an active surface of each of the plurality of chips are directly bonded to the plurality of first conductive vias and the plurality of second conductive vias respectively;
forming a base dielectric layer to cover the first interfacial dielectric layer and sides of the plurality of the chips, wherein the base dielectric layer fills a gap between the plurality of adjacent chips;
removing the first temporary carrier;
fixing the plurality of chips and the first interfacial dielectric layer to a second temporary carrier;
disposing a bridge element on the first interfacial dielectric layer, such that the bridge element partially overlaps the plurality of adjacent chips respectively, wherein a plurality of bridge pads of the bridge element are directly bonded to the plurality of first conductive vias respectively;
forming a second interfacial dielectric layer and a plurality of third conductive vias on the first interfacial dielectric layer and the bridge element, wherein each of the plurality of third conductive vias passes through the first interfacial dielectric layer to be connected to the plurality of second conductive vias respectively;
forming a redistribution circuit structure on the second interfacial dielectric layer and the plurality of third conductive vias;
forming a plurality of conductive bumps on the redistribution circuit structure; and
removing the second temporary carrier.

2. The manufacturing method of the electronic package according to claim 1, wherein forming the first interfacial dielectric layer, the plurality of first conductive vias, and the plurality of second conductive vias comprises:
forming the first interfacial dielectric layer on the first temporary carrier;
removing a plurality of portions of the first interfacial dielectric layer to form a plurality of first through holes and a plurality of second through holes; and
filling a conductive material in the plurality of first through holes and the plurality of second through holes to form the plurality of first conductive vias and the plurality of second conductive vias.

3. The manufacturing method of the electronic package according to claim 1, wherein forming the first interfacial dielectric layer, the plurality of first conductive vias, and the plurality of second conductive vias comprises:
forming the plurality of first conductive vias and the plurality of second conductive vias on the first temporary carrier;
forming the first interfacial dielectric layer that completely covers the first temporary carrier, the plurality of first conductive vias, and the plurality of second conductive vias; and
removing a portion of the first interfacial dielectric layer to expose the plurality of first conductive vias and the plurality of second conductive vias.

4. The manufacturing method of the electronic package according to claim 1, further comprising:
forming a fan-out circuit layer on the first temporary carrier before forming the first interfacial dielectric layer, the plurality of first conductive vias, and the plurality of second conductive vias, wherein the first interfacial dielectric layer covers the fan-out circuit layer, the sides of the plurality of first conductive vias, and the sides of the plurality of second conductive vias, and the plurality of first conductive vias and the plurality of second conductive vias are connected to the fan-out circuit layer respectively.

5. The manufacturing method of the electronic package according to claim 1, further comprising:
thinning the bridge element before forming the redistribution circuit structure.

6. The manufacturing method of the electronic package according to claim 1, further comprising:
connecting the plurality of conductive bumps to a circuit carrier; and
connecting a plurality of conductive balls to the circuit carrier.

7. The manufacturing method of the electronic package according to claim 1, wherein an outer diameter of the third conductive via is smaller than an outer diameter of the second chip pad connected to the second conductive via.

8. The manufacturing method of the electronic package according to claim 1, wherein an outer diameter of the first conductive via is smaller than an outer diameter of the first chip pad connected to the first conductive via.

9. The manufacturing method of the electronic package according to claim 1, wherein an outer diameter of the first conductive via is smaller than an outer diameter of the bridge pad connected to the first conductive via.

10. The manufacturing method of the electronic package according to claim 1, wherein an outer diameter of the second conductive via is smaller than an outer diameter of the second chip pad connected to the second conductive via.

11. The manufacturing method of the electronic package according to claim 1, wherein an outer diameter of the second conductive via is greater than an outer diameter of the third conductive via.

12. An electronic package, comprising:
a sub-package, comprising:
a plurality of chips, arranged in a plane, wherein an active surface of each of the plurality of chips has a plurality of first chip pads and a plurality of second chip pads;
a plurality of first conductive vias, directly bonded to the plurality of first chip pads respectively;
a plurality of second conductive vias, directly bonded to the plurality of second chip pads respectively;
a first interfacial dielectric layer, covering sides of the plurality of first conductive vias and sides of the plurality of second conductive vias, wherein the first interfacial dielectric layer fills a gap between the plurality of adjacent chips;
at least one bridge element, partially overlaps the plurality of adjacent chips respectively, wherein a plurality of bridge pads of the bridge element are directly bonded to the first conductive via respectively;
a second interfacial dielectric layer, located on the first interfacial dielectric layer and the bridge element;
a plurality of third conductive vias, passing through the second interfacial dielectric layer to be connected to the plurality of second conductive vias respectively, wherein an outer diameter of the third conductive via is smaller than an outer diameter of the second chip pad connected to the second conductive via;
a redistribution circuit structure, disposed on the second interfacial dielectric layer and the plurality of third conductive vias; and
a plurality of conductive bumps, disposed on the redistribution circuit structure.

13. The electronic package according to claim 12, wherein an outer diameter of the first conductive via is smaller than an outer diameter of the first chip pad connected to the first conductive via.

14. The electronic package according to claim 12, wherein an outer diameter of the first conductive via is smaller than an outer diameter of the bridge pad connected to the first conductive via.

15. The electronic package according to claim 12, wherein an outer diameter of the second conductive via is smaller than the outer diameter of the second chip pad connected to the second conductive via.

16. The electronic package according to claim 12, wherein an outer diameter of the second conductive via is greater than the outer diameter of the third conductive via.

17. The electronic package according to claim 12, wherein a distribution density of the plurality of first chip pads is greater than a distribution density of the plurality of second chip pads.

18. The electronic package according to claim 12, wherein a thickness of the bridge element is smaller than a thickness of the plurality of chips.

19. The electronic package according to claim 12, further comprising:
a base dielectric layer, covering the first interfacial dielectric layer and sides of the plurality of chips and filling the gap between the plurality of adjacent chips.

20. The electronic package according to claim 12, further comprising:
a circuit carrier, wherein the sub-package is mounted on the circuit carrier.

21. The electronic package according to claim 12, wherein the sub-package further comprises:
a fan-out circuit layer, embedded in the first interfacial dielectric layer and connected to the plurality of first conductive vias and the plurality of second conductive vias.
